(19) United States
(12) Patent Application Publication
(10) Pub. No.: US 2013/0083495 A1
(43) Pub. Date: Apr. 4, 2013

(54) TUNER MODULE

(71) Applicants: Dong Teck MOON, Suwon (KR); Chang Ik Kim, Yongin (KR); Ju Ho Lee, Suwon (KR); Chang Min Seo, Suwon (KR); Eun Young Shin, Seoul (KR); Si Young Kwon, Seoul (KR)

(72) Inventors: Dong Teck MOON, Suwon (KR); Chang Ik Kim, Yongin (KR); Ju Ho Lee, Suwon (KR); Chang Min Seo, Suwon (KR); Eun Young Shin, Seoul (KR); Si Young Kwon, Seoul (KR)

(73) Assignee: SAMSUNG ELECTRO-MECHANICS CO., LTD.

(21) Appl. No.: 13/458,665

(22) Filed: Apr. 27, 2012

(30) Foreign Application Priority Data
Sep. 30, 2011 (KR) 10-2011-0100124

(51) Int. Cl. H05K 1/14

(52) U.S. Cl. 361/736; 361/784

(57) ABSTRACT

There is provided a tuner module used for a television (TV) or a set top box, and more particularly, to a tuner module having a significantly reduce size. The tuner module includes: a tuner including a circuit board having at least one electronic component mounted thereon, and a cover coupled to the circuit board and having an opened bottom portion so as to allow the circuit board to be received therein; and a main board having the tuner mounted on one surface thereof, wherein the main board includes a ground pad formed thereon to correspond to a position in which the tuner is mounted.

### CROSS-REFERENCE TO RELATED APPLICATIONS

This application claims the priority of Korean Patent Application No. 10-2011-0100124 filed on Sep. 30, 2011, in the Korean Intellectual Property Office, the disclosure of which is incorporated herein by reference.

### BACKGROUND OF THE INVENTION

1. Field of the Invention

The present invention relates to a tuner module used for a television (TV) or a set top box, and more particularly, to a tuner module having a minimized size.

2. Description of the Related Art

Generally, a tuner for a TV refers to an apparatus that receives an RF signal (wireless frequency signal) through an antenna and converts the received RF signal into an intermediate frequency (IF) signal and then detects the converted signal to separate and output a video signal and an audio signal.

In the case of a television, a tuner is connected to an antenna through a cable to receive and convert external signals into audio and video signals, and, in the case of a radio, the tuner detects external signals in a circuit for receiving the AM or FM broadcast to extract audio waveforms.

The tuner is mounted within electronic products in a state in which it is attached to a main board performing various functions, and performs several functions by various semiconductor devices or the like, provided on the main board.

In addition, according to the related art, the entire tuner is disposed within a metal case in order to shield electromagnetic waves introduced from the outside. That is, the metal case serves as a protective shield and is configured to electrically connect terminal pins protruded from the metal case to the outside to a main board.

The tuner according to the related art is formed to surround the entire circuit board in which the metal case configures the tuner, such that the size of the tuner is increased by a predetermined amount.

Recently, thin type TVs such as an LCD TV or an LED TV, instead of a cathode ray tube type TV, have been actively developed.

The production of thin type TVs has mainly been focused on a reduction in the thickness of TV, and as a result, various electronic components configuring TVs have limitations in terms of the size or shape thereof.

Therefore, demand for smaller and thinner tuners has increased.

### SUMMARY OF THE INVENTION

An aspect of the present invention provides a thinner and smaller tuner module.

Another aspect of the present invention provides an easily manufactured tuner module.

According to an aspect of the present invention, there is provided a tuner module, including: a tuner including a circuit board having at least one electronic component mounted thereon, and a cover coupled to the circuit board and having an opened bottom portion so as to allow the circuit board to be received therein; and a main board having the tuner mounted on one surface thereof, wherein the main board includes a ground pad formed thereon to correspond to a position in which the tuner is mounted.

In the main board, the ground pad may be electrically connected with the cover of the tuner.

The ground pad and the cover may form a protective shield surrounding an outside of the electronic component mounted on the circuit board.

The ground pad may be formed on one surface of the main board on which the tuner is mounted.

The ground pad may be formed on the other surface of the main board.

The cover may include at least one insertion projection penetrating through the main board to be electrically connected with the ground pad.

The cover may include at least one insertion projection penetrating through the main board to be electrically connected with a ground electrode formed on the other surface of the main board.

The circuit board may include at least one terminal pin protruded from a bottom surface of the circuit board, penetrating through the main board, and electrically connected with amounting electrode formed on a bottom surface of the main board.

The circuit board may include at least one external connection terminal protruded from a bottom surface of the circuit board and electrically connected with a mounting electrode formed on a top plate of the main board.

The tuner module may further include at least one connector having one end connected to the circuit board and the other end penetrating through the cover to be exposed to the outside.

The cover and the ground pad may be electrically and physically connected to each other by a conductive adhesive.

According to another aspect of the present invention, there is provided a tuner module, including: a circuit board having at least one electronic component mounted thereon, the at least one electronic component including a semiconductor package having a tuner function; a cover having the circuit board received therein and connected to the circuit board; and a main board having the cover mounted on one surface thereof, and including a ground pad formed thereon to correspond to a position in which the cover is mounted and having a size corresponding to that of the cover.

The ground pad and the cover may forma protective shield surrounding an outside of the semiconductor package and electronic component mounted on the circuit board.

According to another aspect of the present invention, there is provided a tuner module, including: a circuit board having at least one electronic component mounted thereon, the at least one electronic component including a semiconductor package having a tuner function; a protective shield surrounding the circuit board; and a main board electrically connected to the circuit board, wherein the protective shield includes: a cover having the circuit board received therein and connected to the circuit board to be mounted on the main board; and a ground pad formed on one surface of the main board.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a tuner module according to an embodiment of the present invention;

FIG. 2 is an exploded perspective view of the tuner module shown in FIG. 1;

FIG. 3 is a cross-sectional view taken along line A-A′ of FIG. 1;

FIG. 4 is a cross-sectional view taken along line B-B′ of FIG. 1;

FIG. 5 is an exploded perspective view of a tuner module according to another embodiment of the present invention;

FIG. 6 is a cross-sectional view taken along line C-C′ of FIG. 5; and

FIG. 7 is a cross-sectional view taken along line D-D′ of FIG. 5.

### DETAILED DESCRIPTION OF THE INVENTION

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention. Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component does not exactly reflect its real size.

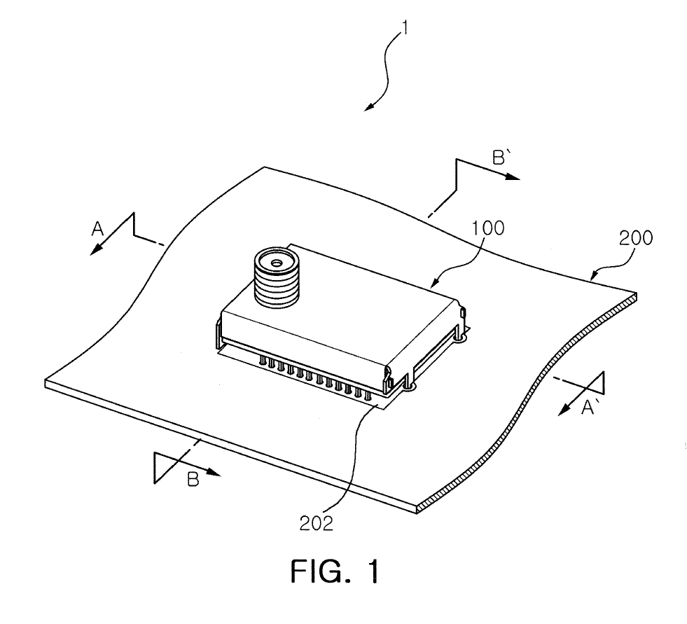

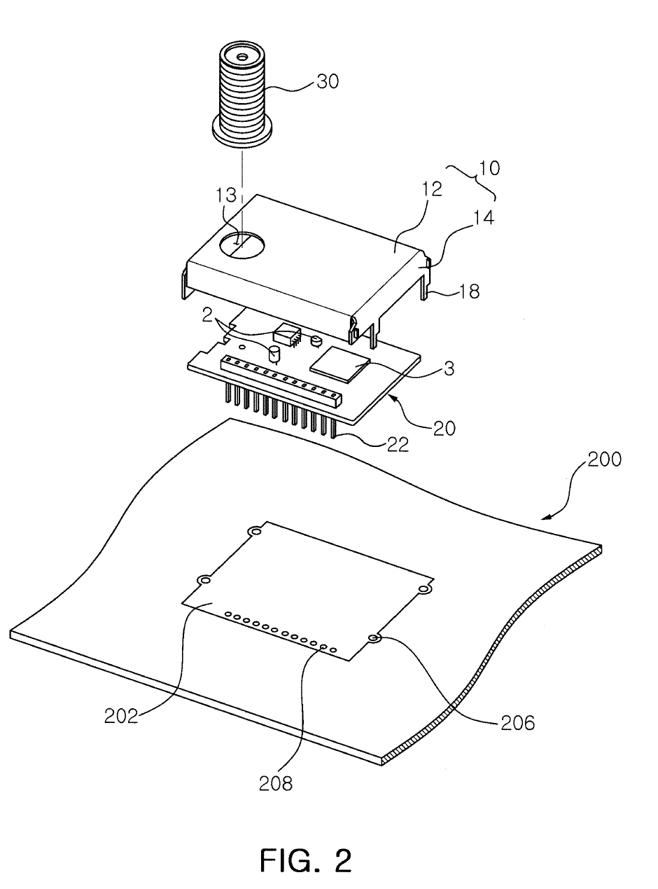

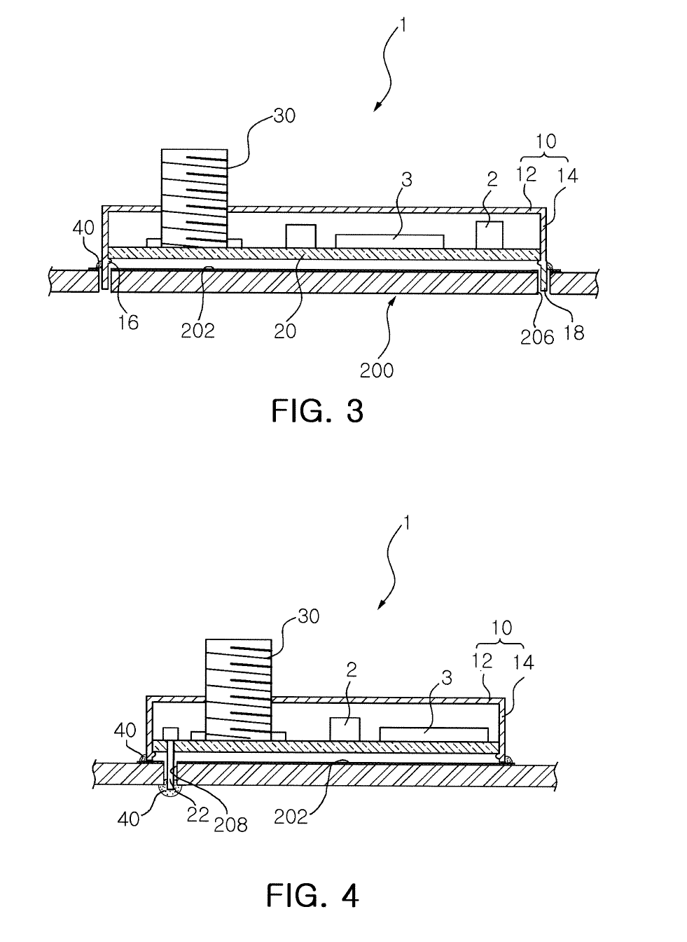

FIG. 1 is a perspective view of a tuner module according to an embodiment of the present invention and FIG. 2 is an exploded perspective view of the tuner module shown in FIG. 1. In addition, FIG. 3 is a cross-sectional view taken along line A-A′ of FIG. 1 and FIG. 4 is a cross-sectional view taken along line B-B′ of FIG. 1.

Referring to FIGS. 1 to 4, a tuner module 1 according to the embodiment of the present invention may include a tuner 100 and a main board 200.

In addition, the tuner 100 according to the embodiment of the present invention may include a circuit board 20, a connector 30, and a cover 10.

A top surface of the circuit board 20 may be provided with mounting electrodes (not shown) for mounting at least one electronic component 2 and wiring patterns (not shown) electrically connecting between mounting electrodes. The circuit board 20 may be a multilayer board formed of a plurality of layers, and conductive vias (not shown) for forming an electrical connection may be formed between respective layers.

In addition, the circuit board 20 according to the embodiment of the present invention may have the at least one electronic component 2 mounted thereon. The least one electronic component 2 may include an active device such as a semiconductor package 2 and a plurality of passive devices.

In particular, the tuner 100 according to the embodiment of the present invention may be provided with a high-integrated semiconductor package 3 in which various devices having various functions are integrated into a single chip. In this case, the semiconductor package 3 may perform both of functions of the tuner 100 or demodulation functions. The semiconductor package 3 is manufactured through a process of manufacturing a separate semiconductor package and may be mounted on the circuit board 20.

The circuit board 20 may includes a plurality of terminal pins 22.

The plurality of terminal pins 22 may be connected to the circuit board 20 while being protruded downwardly of the circuit board 20. In addition, the terminal pins 22 are inserted into terminal holes 208 formed in the main board 200, to be described later, and are bonded to the main board 200 by a conductive adhesive (for example, a conductive solder, or the like) to be electrically and physically connected to the main board 200.

The terminal pins 22 are directly connected to the main board 200 mounted on a TV or a set top box, or the like, and transmit a converted RF signal to the main board 200.

The connector 30 may serve to receive a video signal and an audio signal, respectively, from the outside and transfer the received signals to the circuit board 20. To this end, the connector 30 is formed to have a long cylindrical shape and has one end thereof connected to the circuit board 20 to be electrically connected to the circuit board 20 and the other end thereof penetrating through a through hole 13 of the cover 10, which will described later, to be protruded to the outside.

Meanwhile, since the connector 30 according to the embodiment of the present invention is mounted on the circuit board 20 so as to be vertical thereto, a thickness of the tuner 100 may be relatively reduced, as compared to the case in which the connector 30 is mounted on the circuit board 20 so as to be in parallel therewith.

The cover 10 receives the circuit board 20 therein and protects the at least one electronic component 2 mounted on the circuit board 20 from the outside. In addition, the cover 10 shields an electromagnetic wave introduced from the outside.

Therefore, the cover 10 may be formed to have various shapes or various sizes, as long as it may receive the circuit board 20 therein.

The cover 10 according to the embodiment of the present invention has an open bottom portion, and through the opened bottom portion, the circuit board 20 is mounted within a receiving space of the cover 10.

The cover 10 may include a top plate 12 and a side wall 14.

The top plate 12 forms a top surface of the tuner 100. Therefore, the top plate 12 of the cover 10 is provided with the through hole 13 into which the connector 30 is inserted.

Further, the side wall 14 forms an outer side of the tuner 100. Therefore, the side wall 14 is formed along edges of the circuit board 20 in such a manner as to surround the circuit board 20.

The inside of the side wall 14 may be provided with at least one support protrusion 16 for supporting the circuit board 20. The circuit board 20 may be fixedly mounted into the cover 10 by the support protrusion 16. However, the present invention is not limited thereto and various application may be possible, as long as the circuit board 20 may be firmly fixed into the cover 10, such as the fixation of the circuit board 20 through forming a groove in the side wall 14, the groove having a side surface of the circuit board 20 inserted thereinto.

In addition, a bottom end of the side wall 14 is provided with at least one insertion protrusion 18. The insertion protrusion 18 is provided such that the tuner 100 is coupled with the main board 200 to be described later.

The insertion protrusion 18 maybe formed to a straight pin shape. However, the embodiment of the present invention is not limited thereto. Therefore, a distal end of the insertion protrusion 18 may be bent downwardly from the main board 200 to have a hook shape or may be formed to have an arrowhead shape, or the like. In this case, since the tuner 100 may be firmly fixed to the main board 200 by the insertion protrusion 18, it is possible to prevent the tuner 100 from separating from the main board 200.

In order that the tuner 100 may be stably fixed to the main board 200, the insertion protrusion 18 may be provided in plural and the plurality of insertion protrusions 18 may be formed around respective edges of the tuner 100 inconsideration of a weight center of the tuner 100.

In addition, the top plate 12 and the side wall 14 of the cover 10 according to the embodiment of the present invention may be formed by punching a flat metal plate in a predetermined shape using a press device (not shown) and then bending the metal plate. However, the embodiment of the present invention is not limited thereto. Therefore, according to the embodiment of the present invention, the top plate 12 and the side wall 14 may be separately manufactured and then coupled to be formed integrally with each other.

As shown in FIG. 4, in the cover 10, the bottom end of the side wall 14 may be electrically and physically connected to a ground pad 202 of the main board 200, to be described later, by a conductive bonding part 40.

The main board 200, a substrate mounted on a TV, a set top box, or the like, may have various kinds of electronic component 2 for operating the TV or the set top box. In addition, the main board 200 has the tuner 100 mounted on a surface thereof so as to electrically connect to each other. In this case, the tuner 100 may be at least one tuner.

The main board 200 according to the embodiment of the present invention may be a general printed circuit board (PCB) provided on electronic products. However, the embodiment of the present invention is not limited thereto. Various types of boards known in the art (for example, a ceramic board, a silicon board, a glass board, a flexible board, or the like) may be selectively used, if necessary.

In addition, the main board 200 may be provided with mounting electrodes (not shown) for mounting the at least one electronic component 2 on at least one surface thereof or wiring patterns, electrically connecting between the mounting electrodes, a ground electrode, and the like.

The main board 200 according to the embodiment of the present invention may be a multilayer board formed of a plurality of layers, each layer being provided with circuit patterns (not shown).

In addition, the main board 200 according to the embodiment of the present invention may include the mounting electrodes formed on a top surface thereof, the circuit patterns formed inside the main board 200, and the conductive vias (not shown) electrically connecting the circuit patterns and the mounting electrodes. In addition, the main board 200 according to the embodiment of the present invention maybe provided with a cavity (not shown) allowing the electronic component 2 to be mounted therein.

In addition, the main board 200 according to the embodiment of the present invention may have the ground pad 202 mounted on the top plate 12. The ground pad 202 may be formed to correspond to the exterior of the tuner 100 mounted on the main board 200.

The embodiment of the present invention exemplarily describes the case in which the ground pad 202 is formed to have a substantially rectangular shape along the outer side of the tuner 100 on the top surface of the main board 200. However, the main board 200 according to the embodiment of the present invention is not limited thereto and may be variously formed to correspond to the shape of the tuner 100, such as a circular shape or an oval shape, or the like.

In addition, the main board 200 according to the embodiment of the present invention may include a through hole 206 into which the least one insertion protrusion 18 of the tuner 100 is inserted and terminal holes 208 into which the terminal pins 22 are inserted.

The through hole 206 may be at least one through hole, and the least one through hole 206 may be formed to correspond to a position in which the at least one insertion protrusion 18 of the tuner 100 is disposed. In addition, although not shown, the ground electrode may be formed around an outer circumference of the through hole 206 in the bottom surface of the main board 200 if necessary. In this case, the ground electrode may be electrically and physically coupled with the insertion protrusion 18 inserted into the through hole 206 by a conductive adhesive, or the like.

The terminal holes 208 may be provided in plural to correspond to positions in which the plurality of terminal pin 22 of the tuner 100 are disposed. In addition, the mounting electrodes may be formed around outer circumferences of the terminal holes 208 in the bottom surface of the main board 200. The mounting electrodes may be electrically and physically coupled with the terminal pins 22 inserted into the terminal holes 208 by the conductive bonding part 40.

In this case, the conductive bonding part 40 according to the embodiment of the present invention may be formed of various kinds of material having conductivity. For example, the conductive bonding part may be formed of a conductive adhesive, a conductive solder, or the like, A resin material including conductive powder may be used in the case of the conductive adhesive while a lead-free solder including stannum (Sn) and silver (Ag) maybe used in the case of solder. However, the embodiment of the present invention is not limited thereto, and the conductive bonding part may be formed by welding (for example, a laser welding), or the like.

The tuner module according to the embodiment of the present invention is not limited to the foregoing embodiment, and various application may be possible.

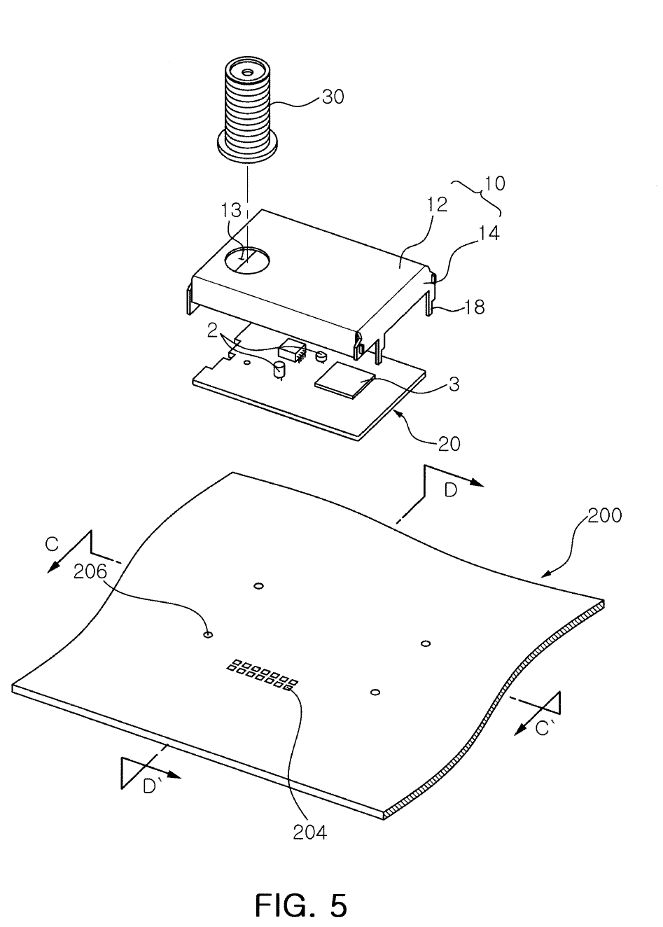

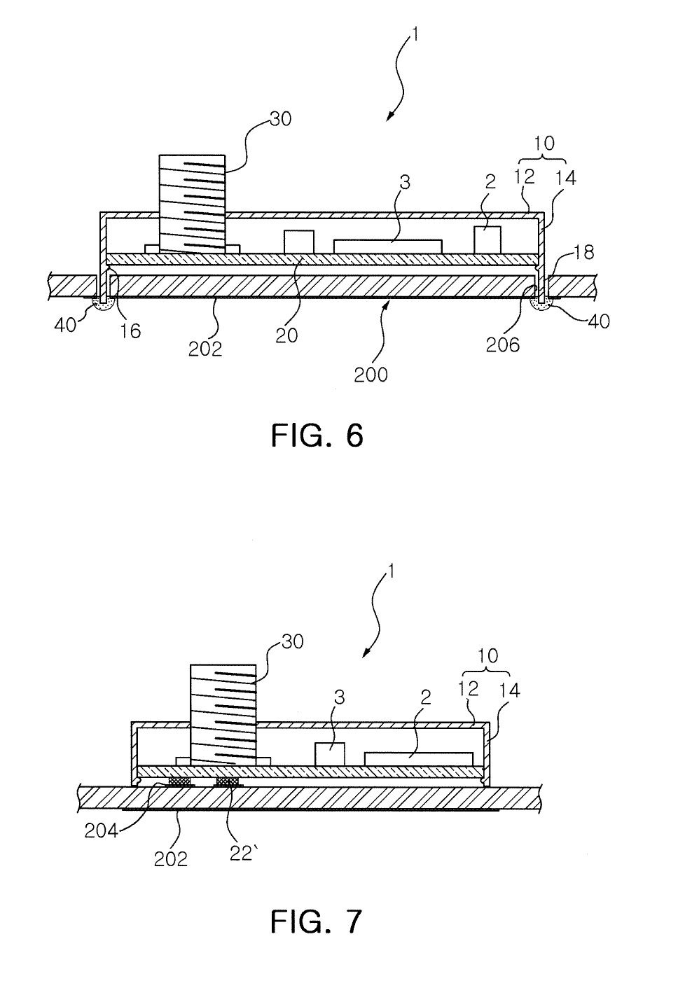

FIG. 5 is an exploded perspective view of a tuner module according to another embodiment of the present invention, FIG. 6 is a cross-sectional view taken along line C-C′ of FIG. 5, and FIG. 7 is a cross-sectional view taken along line D-D′ of FIG. 5.

Referring to FIGS. 5 through 7, the tuner module according to the embodiment of the present invention is configured similar to the foregoing embodiment of the present invention, but partially different therefrom, in terms of the configurations of the terminal pins 22 and the main board 200 of the tuner 100.

As shown in FIG. 7, the tuner 100 according to the embodiment of the present invention includes an external connection terminal 22′ protruded from a bottom surface of the circuit board 20, in the form of a bump, rather than the terminal pins 22. In this case, the external connection terminal 22′ may be formed to have a solder ball or a solder bump shape.

Therefore, the top plate 12 of the main board 200 according to the embodiment of the present invention may be provided with an electrode pad 204 electrically connected to the external connection terminal 22′ of the tuner 100.

In addition, the bottom surface of the main board 200 according to the embodiment of the present invention is provided with the ground pad 202. Therefore, in the tuner module according to the embodiment of the present invention, both of the circuit board 20 and the external connection terminal 22′ are disposed in a protective shield formed by the cover 10 and the ground electrode 202, thereby allowing for a further increase in shielding effects.

As set forth above, in the tuner module according to the embodiment of the present invention, the protective shield maybe formed by the cover provided in the tuner and the ground pad provided on the main board. Therefore, the electronic component mounted on the circuit board of the tuner may be disposed in the protective shield, to be protected from electromagnetic waves in all directions.

In addition, the tuner module according to the embodiment of the present invention includes only the cover having an open bottom portion, rather than having the entire protective shield formed therein. The tuner may be manufactured by only coupling the circuit board having the connecter mounted thereon and the cover.

Further, the ground pad provided on the main board may be formed together the wiring patterns during a process of forming the wiring patterns on the main board and therefore, a separate manufacturing process thereof is not included.

That is, in the tuner module according to the embodiment of the present invention, the protective shield shielding the circuit board of the tuner is completed by only mounting the tuner on the main board. Accordingly, when the tuner is manufactured, the processes according to the related art performed for forming the protective shield in such a manner as to completely surround the entire circuit board may be omitted.

In addition, since the cover of the tuner according to the embodiment of the present invention is directly electrically connected to the ground pad or the ground electrode formed on a top portion of the main board, electrically connecting the cover to the ground pattern or the ground electrode provided on the circuit board of the tuner may not required.

According to the tuner module according to the embodiments of the present invention, a tuner and a tuner module, the manufacturing of which is significantly facilitated and simplified, as compared with the case of the related art, may be obtained. In addition, according to the tuner module according to the embodiments of the present invention, several processes maybe omitted as compared with the case of the related art, whereby manufacturing costs may be more significantly reduced than that of the related art.

In addition, according to the embodiments of the present invention, the thickness of the tuner may be significantly reduced due to the configuration of the cover having the open bottom surface, without a separate chassis provided in the tuner. Therefore, the tuner may be easily mounted on a thin type TV or set top box.

Meanwhile, the tuner module according to the present invention is not limited to the foregoing embodiments, but various modifications may be made by those skilled in the art without departing from the spirit and scope of the present invention.

For example, although the foregoing embodiments describe the tuner provided with only a single connector, by way of example, the embodiment of the present invention is not limited thereto, the tuner may include a plurality of connectors, if necessary.

In addition, the foregoing embodiments describe the case in which the connector is disposed to be vertical to the main board, by way of example. However, various application may be possible if necessary, such as the case in which the connector is disposed in parallel with the main board, or the like.

In addition, although the foregoing embodiments describe the case in which the cover is provided with the insertion protrusion and the insertion protrusion is connected to the ground electrode or the ground pad on the main board, by way of example, the embodiments of the present invention are not limited thereto. That is, the tuner may be configured such that the insertion protrusion is removed and the bottom end of the cover directly contacts the main board to be bonded thereto. In this case, the ground pad may be disposed on a surface of the main board and the bottom end of the cover is directly bonded to the ground pad.

In addition, although the foregoing embodiments of the present invention describe the tuner for receiving a TV, by way of example, the present invention is not limited thereto and a wide range of tuner module may be used, as long as the tuner module includes a protective shield shielding a plurality of chips on a substrate.

What is claimed is:

1. A tuner module, comprising:
a tuner including a circuit board having at least one electronic component mounted thereon, and a cover coupled to the circuit board and having an opened bottom portion so as to allow the circuit board to be received therein; and
a main board having the tuner mounted on one surface thereof,
wherein the main board includes a ground pad formed thereon to correspond to a position in which the tuner is mounted.

2. The tuner module of claim 1, wherein in the main board, the ground pad is electrically connected with the cover of the tuner.

3. The tuner module of claim 2, wherein the ground pad and the cover form a protective shield surrounding an outside of the electronic component mounted on the circuit board.

4. The tuner module of claim 1, wherein the ground pad is formed on one surface of the main board on which the tuner is mounted.

5. The tuner module of claim 1, wherein the ground pad is formed on the other surface of the main board.

6. The tuner module of claim 5, wherein the cover includes at least one insertion projection penetrating through the main board to be electrically connected with the ground pad.

7. The tuner module of claim 1, wherein the cover includes at least one insertion projection penetrating through the main board to be electrically connected with a ground electrode formed on the other surface of the main board.

8. The tuner module of claim 1, wherein the circuit board includes at least one terminal pin protruded from a bottom surface of the circuit board, penetrating through the main board, and electrically connected with a mounting electrode formed on a bottom surface of the main board.

9. The tuner module of claim 1, wherein the circuit board includes at least one external connection terminal protruded from a bottom surface of the circuit board and electrically connected with a mounting electrode formed on a top plate of the main board.

10. The tuner module of claim 1, further comprising at least one connector having one end connected to the circuit board and the other end penetrating through the cover to be exposed to the outside.

11. The tuner module of claim 1, wherein the cover and the ground pad are electrically and physically connected to each other by a conductive adhesive.

12. A tuner module, comprising:
a circuit board having at least one electronic component mounted thereon, the at least one electronic component including a semiconductor package having a tuner function;
a cover having the circuit board received therein and connected to the circuit board; and
a main board having the cover mounted on one surface thereof, and including a ground pad formed thereon to correspond to a position in which the cover is mounted and having a size corresponding to that of the cover.

13. The tuner module of claim 12, wherein the ground pad and the cover form a protective shield surrounding an outside of the semiconductor package and electronic component mounted on the circuit board.

14. A tuner module, comprising:
a circuit board having at least one electronic component mounted thereon, the at least one electronic component including a semiconductor package having a tuner function;
a protective shield surrounding the circuit board; and
a main board electrically connected to the circuit board,
wherein the protective shield includes:
a cover having the circuit board received therein and connected to the circuit board to be mounted on the main board; and
a ground pad formed on one surface of the main board.
